(19) United States
(12) Patent Application Publication
(10) Pub. No.: US 2017/0208705 A1
(43) Pub. Date: Jul. 20, 2017

(54) IMMERSION COOLING OF POWER CIRCUIT

(71) Applicant: Hamilton Sundstrand Corporation, Charlotte, NC (US)

(72) Inventors: Josh C. Swenson, Rockford, IL (US); Christian Miller, Beloit, WI (US); Robert C. Cooney, Janesville, WI (US)

(21) Appl. No.: 14/996,472

(22) Filed: Jan. 15, 2016

(51) Int. Cl. H05K 7/20

(52) U.S. Cl. CPC H05K 7/20272

(57) ABSTRACT

A cooling arrangement has a circuit board and a plurality of electronic components in operable communication with the circuit board. An enclosure is attached to the circuit board being configured to retain a fluid around at least one of the plurality of electronic components. The circuit board with the enclosure is attached thereto being removably connectable to a motherboard.

### BACKGROUND OF THE INVENTION

This application relates to immersion cooling of power electronic circuits.

Modern systems are becoming more and more complex and, as a result, complex electrical controls are provided for many such systems. One example system would be aerospace equipment, such as an aircraft.

Control modules for such system often include a motherboard and a plurality of line removable modules (“LRMs”) or other circuit boards. One particular type of LRM carries a number of power transistors forming solid state power controllers (“SSPC”). Power transistors have unique cooling challenges.

One known type of power transistors is a metal oxide field effect transistor (“MOSFET”). Although MOSFETs are mentioned, other types of solid state power controllers also raise similar challenges.

Modern control modules may include a very high number of such transistors and electronic controls. The heat generated by these transistors raises challenges with cooling.

Solid state power controllers are subject to transient heat loss due to a number of reasons, including load in-rush currents, fly back when inductive load currents are braked, lightning strikes, overcurrent faults that must be carried for a short period of time prior to turning the SSPC off, etc.

In general, fluid immersion cooling for control circuits have surrounded the entire control module. This raises challenges, as a designer of modern control modules would like to be able to tailor a particular combination of motherboard and circuit boards. Further, when the entire control module is surrounded by cooling fluid, it is difficult to replace any one LRM. Fluid cooling circuits typically include a hermetic seal and, thus, are not prone to easy repair.

### SUMMARY OF THE INVENTION

A cooling arrangement has a circuit board and a plurality of electronic components in operable communication with the circuit board. An enclosure is attached to the circuit board being configured to retain a fluid around at least one of the plurality of electronic components. The circuit board with the enclosure is attached thereto being removably connectable to a motherboard.

These and other features may be best understood from the following drawings and specification.

### BRIEF DESCRIPTION OF THE DRAWINGS

FIG. 1 shows an example control module.

FIG. 2 shows a circuit board within the FIG. 1 control module.

FIG. 3A shows a first embodiment of an optional feature.

FIG. 3B shows a second embodiment.

FIG. 3C shows a third embodiment.

FIG. 4 shows an alternative circuit board.

FIG. 5 shows a control module utilizing the FIG. 4 embodiment.

FIG. 6A shows an optional feature.

FIG. 6B shows another embodiment.

FIG. 6C shows yet another embodiment.

### DETAILED DESCRIPTION

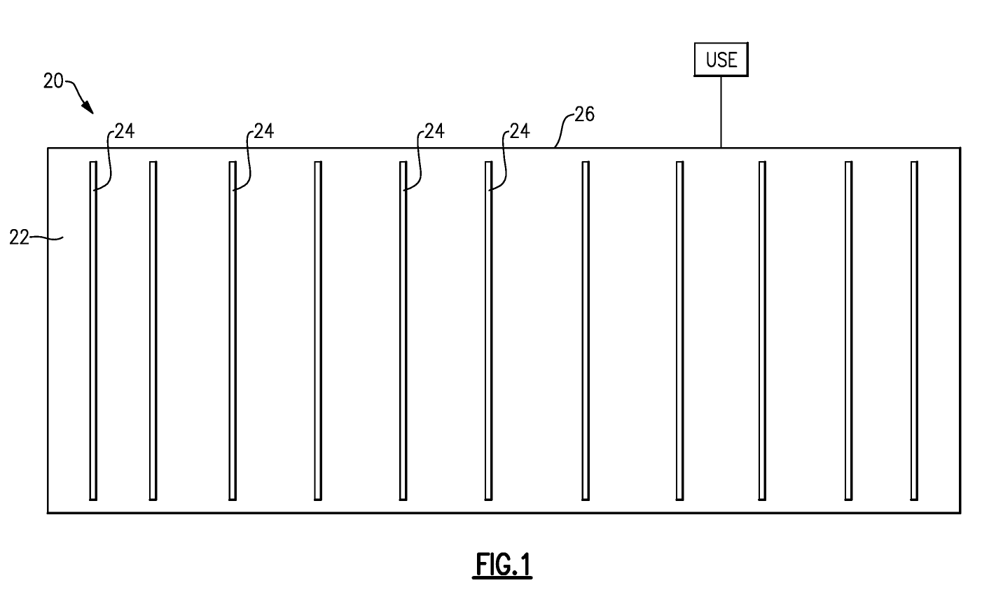

FIG. 1 shows a control module 20 including a motherboard 22 and a plurality of removable circuit boards 24. The module 20 communicates control signals to and from a use, such as a system on an aircraft. Boards 24 may be LRMs, but other board types may be used. As known, the boards are electrically connected to the motherboard. An outer housing 26 surrounds the boards 22 and 24. Of course, this view is highly schematic.

As mentioned above, it would be desirable to be able to freely replace the circuit boards 24 on the motherboard 22 to achieve tailored control features for a particular system. Also, some replacement may be required for maintenance purposes. In addition, it is desirable to provide cooling for elements on the circuit boards 24. This becomes particularly valuable if the circuit boards are power distribution circuits carrying power transistors.

FIG. 2 shows a circuit board embodiment 24. As shown, control circuits or switches 28 communicate with transistors in an enclosure 30. The enclosures 30 each surround an individual power transistor or group of power transistors and/or other components that can benefit from additional cooling. In an embodiment the board 24 has connections to be secured to motherboard 22.

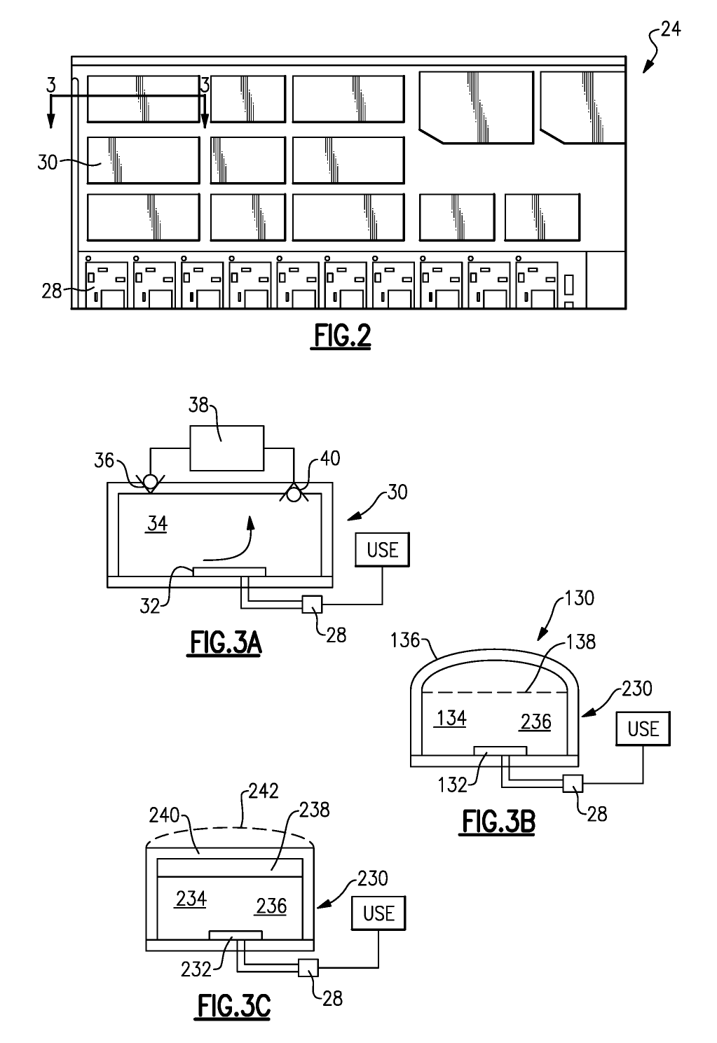

FIG. 3A shows a first embodiment wherein a power transistor 32 is mounted within the enclosure 30. Internal chamber 34 is filled with a dielectric cooling fluid. As shown by the curved line, fluid flowing adjacent to the power transistor 32 is heated and flows away, towards the enclosure wall, where it may dissipate heat to the outer environment.

As mentioned above, much of the heat generated by the transistor 32 may be transient. As the fluid absorbs this heat, the fluid expands such that the pressure within the chamber 34 rises. Pressure relief valve 36 may allow fluid to then flow outward of the enclosure. A holding container 38 is shown schematically along with a return inlet 40. Once the fluid within chamber 34 cools, the fluid may return from holding chamber 38 into inlet 40. In this manner, the enclosure 30 facilitates handling an expanding fluid. In some embodiments the fluid may boil as result of absorbing the heat, increasing the pressure and assisting heat transfer.

As an alternative, the pressure relief valve may simply vent the fluid to the environment.

FIG. 3B shows an embodiment 130 wherein a power transistor 132 is placed within a chamber 134. The outer housing is shown to be flexible at 136. A nominal position is shown in phantom at 138. As the fluid with chamber 134 expands, it can force the enclosure to the expanded position 136. Again, this will allow the enclosure 130 to facilitate expansion of the fluid as it heats.

Another embodiment 230 is shown in FIG. 3C. A power transistor 232 is placed within a chamber 234. Within chamber 234, there is a liquid cooling fluid level 236 and a compressible gas level 238. As the fluid 236 expands, it can compress the gas 238 allowing expansion of the fluid.

Notably, the FIG. 3C embodiment may be used in conjunction with a flexible housing such as shown in FIG. 3B. This is shown schematically, as the housing moves from a nominal position 240 to an expanded position 242.

As shown in each of FIGS. 3A-3C, switches work with the transistors 32/132/232 to communicate signals to a use, typically through the motherboard.

With these embodiments, individual line removable modules 24 may be removed from a control module 20 without the complexity of removing the cooling liquid from the enclosure. Also, with these embodiments, individual transistors or groups of transistors, and the associated enclosures, may be removed from the circuit board 24 for replacement or repair.

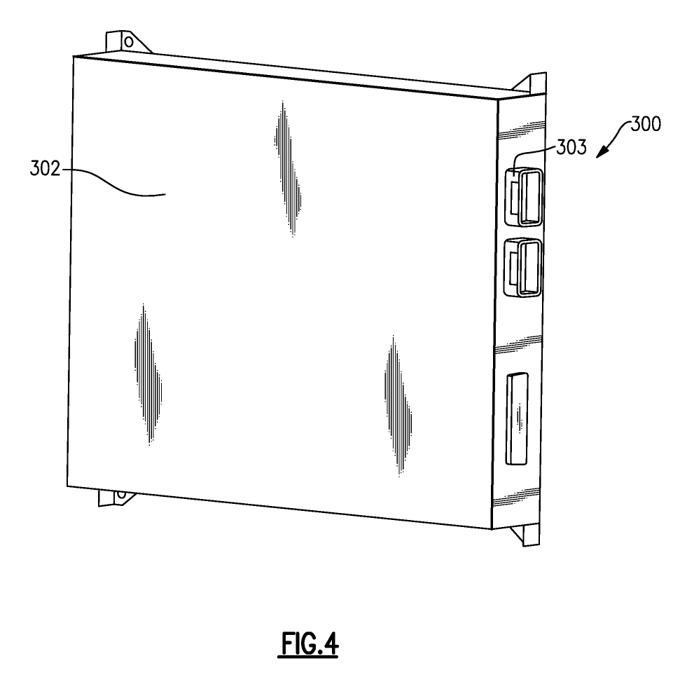

FIG. 4 shows another embodiment 300 wherein an entire circuit board 24 is placed within an enclosed immersion cooling housing or enclosure 302. Housing 302 may be provided with heat transfer surfaces on its outer periphery, such as roughened surface or provided with other heat transfer enhancing features such as fins, etc. The enclosure is filled with dielectric cooling fluid and the expansion features of FIGS. 3A, 3B, and 3C may be applied to the entire housing. Of course, appropriate electrical connection shown at 303 extends outwardly of the enclosure.

FIG. 5 shows a control module 310 having a motherboard 22, a plurality of removable circuit boards 124, which are not provided with immersion cooling, and an enclosed circuit board 300 as shown in FIG. 4. Again, the module 310 communicates with a use.

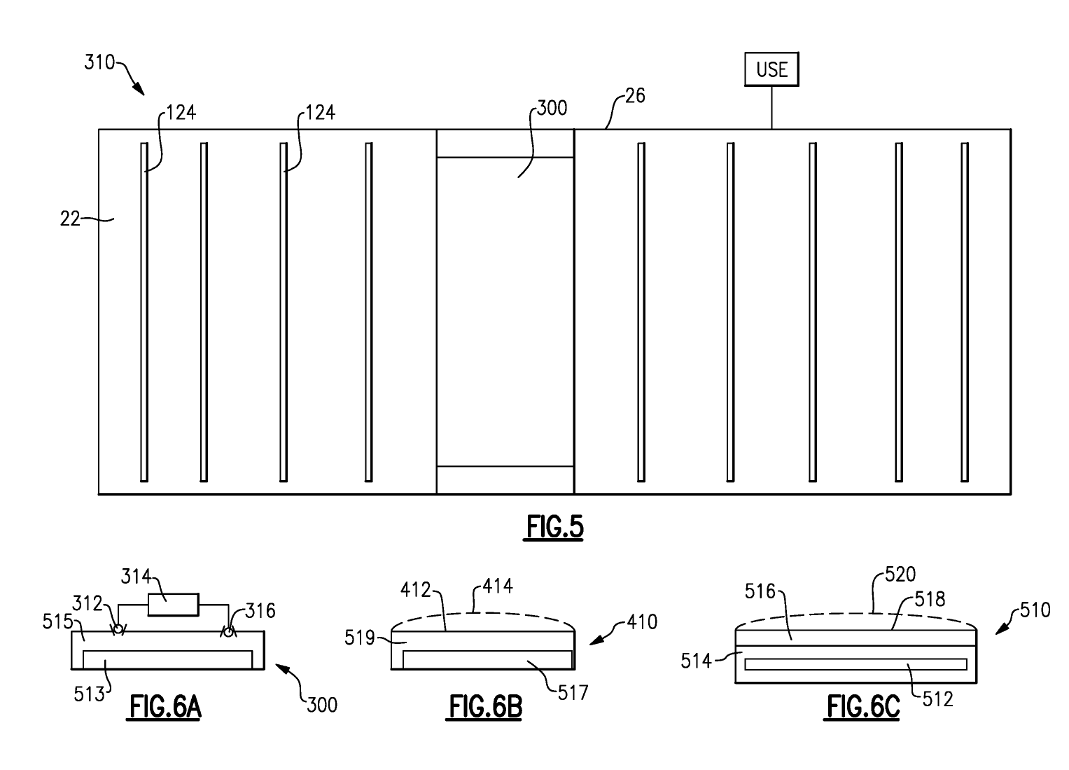

The enclosed circuit board 300 is illustrated in FIG. 6A, wherein the board 513 is received within a fluid 515, with a pressure relief valve 312 leading to a holding container 314, and an inlet 316. This embodiment will operate to allow expansion of the fluid, and movement of the fluid outwardly of the enclosure should it exceed a predetermined pressure. As such, it operates similar to the FIG. 3A embodiment.

FIG. 6B shows an enclosed circuit board 410, which may replace the enclosed board 300 of FIG. 5, wherein the board 517 is received within a fluid 519, in which an enclosure has a nominal wall location 412, but is flexible such that it can expand as shown at 414 to accommodate expansion of the liquid within the enclosure. As such, it functions like the FIG. 3B embodiment.

FIG. 6C shows an enclosure 510, wherein the board 512 itself is received within a fluid 514. The fluid is a liquid. A layer of compressible gas 516 is also included. As the liquid 514 expands, it can compress the gas layer 516. In addition, the enclosure 518 may optionally have a flexible wall such that it can expand as shown at 520. As such, this is similar to the FIG. 3C embodiment.

In sum, a control module 20, 310 has a motherboard 22 and a plurality of removable circuit boards 24/124/300. At least one of the circuit boards is provided with immersion cooling of an electronic component surrounded by an enclosure that does not enclose others of the plurality of circuit boards.

In embodiments, a circuit board 24/300 has a plurality of electronic components, with an immersion cooling fluid within an enclosure 30/302, such that the circuit board and enclosure can be removed or inserted as a unit into a motherboard without releasing the fluid from the enclosure.

Providing the enclosed cooling facilitates the specific tailoring of the circuit boards 24 or 300. Further, this arrangement facilitates the replacement or repair of individual line removable modules or circuits.

The assembly can facilitate the tailoring of a combination of boards. Typically, a system would have a number of different module/board types such as a power supply, microprocessor, discrete I/O communications, and SSPC modules. As different customers have different numbers and types of loads to be controlled, a mix of modules can be tailored to particular needs. For example, one customer may need several low current DC SSPCs while another might need a mix of AC and DC of various load currents.

It is desirable to be able to have high loss boards (high current especially AC) be specially cooled while the rest of the system be traditional boards. This disclosure achieves such a goal.

Although an embodiment of this invention has been disclosed, a worker of ordinary skill in this art would recognize that certain modifications would come within the scope of this invention. For that reason, the following claims should be studied to determine the true scope and content of this invention.

1. A cooling arrangement comprising:
a circuit board;
a plurality of electronic components in operable communication with the circuit board; and
an enclosure attached to the circuit board being configured to retain a fluid around at least one of the plurality of electronic components, said circuit board with the enclosure attached thereto being removably connectable to a motherboard.

2. The cooling arrangement as set forth in claim 1, wherein said plurality of said electronic components includes at least one power transistor and at least one control circuit, and said enclosure enclosing said at least one power transistor, said at least one control circuit being outside said enclosure.

3. The cooling arrangement as set forth in claim 2, wherein there are a plurality of said transistors and a plurality of enclosures each enclosing one of said plurality of transistors, with a plurality of control circuits positioned outside of said plurality of enclosures.

4. The cooling arrangement as set forth in claim 1, wherein said plurality of electronic components includes a transistor and a control circuit received within said enclosure.

5. The cooling arrangement as set forth in claim 1, wherein said enclosure is provided with a feature to allow expansion of a fluid within said enclosure.

6. The cooling arrangement as set forth in claim 5, wherein a pressure relief valve allows fluid to move outwardly of a chamber surrounding said transistor.

7. The cooling arrangement as set forth in claim 5, wherein said enclosure includes at least one flexible wall, said wall can expand to accommodate an increase in volume of said fluid.

8. The cooling arrangement as set forth in claim 7, wherein said fluid is a liquid and said enclosure is also provided with a compressible gas, with said compressible gas allowing expansion of said liquid.

9. The cooling arrangement as set forth in claim 5, wherein said fluid is a liquid and said enclosure is also provided with a compressible gas, with said compressible gas allowing expansion of said liquid.

10. A control module comprising:
a motherboard and a plurality of removable circuit boards, and at least one of said circuit boards being provided with immersion cooling of an electronic component surrounded by an enclosure that does not enclose others of said plurality of circuit boards.

11. The control module as set forth in claim 10, wherein said at least one of said circuit boards has at least one power transistor and at least one control circuit, and said enclosure enclosing said at least one power transistor, said at least one control circuit being outside said enclosure.

12. The control module as set forth in claim 11, wherein there are a plurality of said transistors and a plurality of enclosures each enclosing one of said plurality of transistors, with a plurality of control circuits positioned outside of said plurality of enclosures.

13. The control module as set forth in claim 12, wherein said enclosure is provided with a feature to allow expansion of a fluid within said enclosure.

14. The control module as set forth in claim 10, wherein said at least one of said circuit board is enclosed entirely in said enclosure and at least one circuit board including a transistor and a control circuit all received within said enclosure, with others of said plurality of circuit boards being outside said enclosure.

15. The control module as set forth in claim 14, wherein said enclosure is provided with a feature to allow expansion of a fluid within said enclosure.

16. The control module as set forth in claim 10, wherein said enclosure is provided with a feature to allow expansion of a fluid within said enclosure.

17. The control module as set forth in claim 16, wherein a pressure relief valve allows fluid to move outwardly of a chamber surrounding said transistor.

18. The control module as set forth in claim 16, wherein said enclosure includes at least one flexible wall, said wall can expand to accommodate an increase in volume of said fluid.

19. The control module as set forth in claim 18, wherein said fluid is a liquid and said enclosure is also provided with a compressible gas, with said compressible gas allowing expansion of said liquid.

20. The control module as set forth in claim 16, wherein said fluid is a liquid and said enclosure is also provided with a compressible gas, with said compressible gas allowing expansion of said liquid.
